(19) United States
(12) Patent Application Publication
(10) Pub. No.: US 2025/0117539 A1
(43) Pub. Date: Apr. 10, 2025

(54) SYSTEMS AND METHODS TO SIMULATE THE MOVEMENT AND INTERACTION OF OBJECTS ON MODULAR OMNIDIRECTIONAL ACTUATED FLOORS

(71) Applicant: DISNEY ENTERPRISES, INC., Burbank, CA (US)

(72) Inventors: Jack Wetherell, Burbank, CA (US); Robert J. Bristow, Shadow Hills, CA (US); Lanny S. Smoot, Thousand Oaks, CA (US); Frank D. Mezzatesta, III, Glendale, CA (US)

(21) Appl. No.: 18/376,930

(22) Filed: Oct. 5, 2023

(51) Int. Cl. G06F 30/20

(52) U.S. Cl. CPC G06F 30/20

(57) ABSTRACT

Systems and methods to simulate the movement and interaction of objects on modular omnidirectional actuated floors are disclosed herein. A system may include a processor configured to generate a set of particles along a boundary of a contact surface of an object on a modular floor including a plurality of tiles configured to move independently. The processor may also be configured to assign a linear velocity to each particle of the set of particles. The processor may also be configured to assign an angular velocity to each particle of the set of particles. The processor may also be configured to simulate the motion of the object on the modular floor based on the assigned linear and angular velocities. Additional systems and associated methods are also disclosed.

### FIELD

The present application relates to systems and methods of simulating the movement and interaction of objects on modular, omnidirectional actuated floors.

### BACKGROUND

The simulation of the motion and interaction of objects and walking participants on a modular and omnidirectional actuated floor can be difficult and intractable. Such is especially true for large floor sizes and large object and walker counts. This is due to the kinematic, dynamic, and rotational behavior driven by many static and dynamic friction effects, whose effects must be captured precisely to produce realistic behavior.

For example, simulating the motion and interaction of objects on a modular and omnidirectional actuated floor can be difficult due, in part, to the modularity of the floor itself, as each section of the floor can drive objects in contact in different directions, resulting in complex linear and rotational dynamics, which is the result of competing friction effects and the nature of a rigid body. The simulation can also be difficult due, in part, to omnidirectionality, as each floor section can drive different connection points in arbitrary directions and speeds.

To produce realistic and computationally tractable behavior in simulation, cases such as these need to be captured accurately without the need for an explicit model of the friction-based actuation that produces the behavior in reality.

### BRIEF SUMMARY

A system for simulating a motion of an object on a modular floor including a plurality of tiles configured to move independently is disclosed herein. The system includes a processor. The processor is configured to generate a set of particles along a boundary of a contact surface of the object. The processor is further configured to assign a linear velocity to each particle of the set of particles. The processor is further configured to assign an angular velocity to each particle of the set of particles. The processor is further configured to simulate the motion of the object on the modular floor based on the assigned linear and angular velocities.

Optionally, in some embodiments, the system includes the modular floor.

Optionally, in some embodiments, the processor is configured to determine a set of tiles of the modular floor in contact with the object based on arbitrary mesh collision.

Optionally, in some embodiments, the linear velocity assigned to each particle is based on a velocity of the tile on which the particle is positioned.

Optionally, in some embodiments, the processor is configured to determine a center of rotation of the contact surface based on an average of the particle positions.

Optionally, in some embodiments, the angular velocity assigned to each particle is based on a vector product of the particle's linear velocity and distance from the center of rotation.

Optionally, in some embodiments, the assigned linear and angular velocities are averaged to simulate the motion of the object.

Optionally, in some embodiments, the processor is configured to calculate a standard deviation of the assigned linear velocities.

Optionally, in some embodiments, the processor is configured to determine a tension stress applied to at least one of the object or the modular floor based on the standard deviation of the assigned linear velocities.

Optionally, in some embodiments, the processor is configured to calculate a standard deviation of the assigned angular velocities.

Optionally, in some embodiments, the processor is configured to determine a torsion stress applied to at least one of the object or the modular floor based on the standard deviation of the assigned angular velocities.

A method is disclosed herein. The method includes generating, by a processor, a set of particles along a boundary of a contact surface of an object in contact with a modular floor, the modular floor comprising a plurality of tiles configured to move independently to induce a motion of the object on the modular floor. The method further includes assigning, by the processor, a linear velocity to each particle of the set of particles. The method further includes assigning, by the processor, an angular velocity to each particle of the set of particles. The method further includes simulating, by the processor, the motion of the object on the modular floor based on the assigned linear and angular velocities.

Optionally, in some embodiments, the method further includes determining, by the processor, a set of tiles in contact with the object based on arbitrary mesh collision.

Optionally, in some embodiments, the linear velocity assigned to each particle is based on a velocity of the tile on which the particle is positioned.

Optionally, in some embodiments, the method further includes determining, by the processor, a center of rotation of the contact surface based on an average of the particle positions.

Optionally, in some embodiments, the angular velocity assigned to each particle is based on a vector product of the particle's linear velocity and distance from the center of rotation.

Optionally, in some embodiments, the simulating the motion of the object includes averaging the assigned linear and angular velocities.

Optionally, in some embodiments, the method further includes calculating, by the processor, a standard deviation of the assigned linear velocities.

Optionally, in some embodiments, the method further includes determining, by the processor, a tension stress applied to at least one of the object or the modular floor based on the standard deviation of the assigned linear velocities.

Optionally, in some embodiments, the method further includes calculating, by the processor, a standard deviation of the assigned angular velocities.

Optionally, in some embodiments, the method further includes determining, by the processor, a torsion stress applied to at least one of the object or the modular floor based on the standard deviation of the assigned angular velocities.

### BRIEF DESCRIPTION OF THE DRAWINGS

FIG. 1 illustrates an example motion system including a modular floor formed with a plurality of active tiles.

FIG. 2 illustrates an example disk assembly for use in a motion system of the present disclosure.

FIG. 3 illustrates an exploded view of the disk assembly of FIG. 2.

FIGS. 4A-4D illustrate various orientations of a tilted contact disk of the disk assembly of FIG. 2 that define respective directions a supported object is moved by the disk assembly.

FIG. 5 illustrates a portion of an active tile including an array of disk assemblies.

FIG. 6 illustrates an example computing system for implementing various examples of the present disclosure.

FIG. 7A illustrates a modular floor having two active tiles acting on an object in a first manner.

FIG. 7B illustrates a modular floor having two active tiles acting on an object in a second manner.

FIG. 7C illustrates a modular floor having three active tiles acting on an object.

FIGS. 8A-8D illustrate examples of simulating movement of an object on a multi-tile modular floor.

FIG. 9 illustrates a method of simulating movement of an object on a multi-tile modular floor.

### DETAILED DESCRIPTION

According to the present disclosure, motion of an object on a modular floor composed of an arbitrary system of omnidirectional actuated tiles or modules may be simulated. For example, a large modular floor with many objects and user participants (e.g., “walkers”) may be simulated efficiently, realistically, and tractably. The systems and methods disclosed herein may define a realistic behavior of linear and rotational motion of objects due to complex interaction of competing rigid bodies and rotational friction-based actuation. In this manner, the systems and methods disclosed herein may produce accurate and realistic simulation models with very low computational cost. Such systems and methods may also allow the predation of stresses and potential damage to the modular floor. In this manner, the simulations may be used to create an installation design or otherwise prove the feasibility or functionality of a modular floor (e.g., predesign or previsualization), such as predicting one or more forces to enable the design and installation of a modular floor in different scenarios (e.g., that may not be possible without simulation due to difficulty of accurately calculating the actual forces, object movements, etc.).

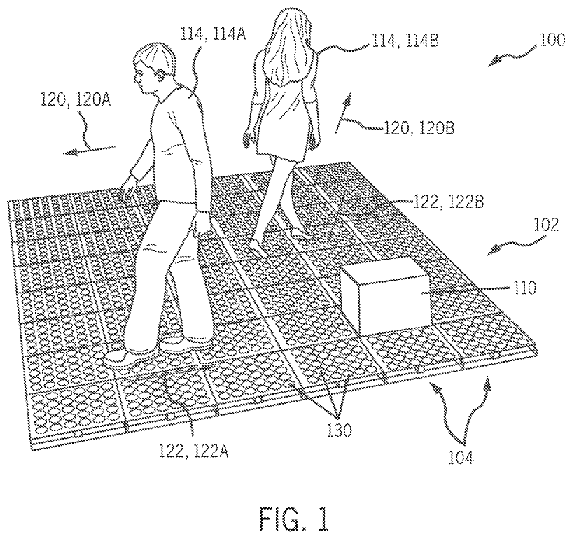

FIG. 1 illustrates an example motion system 100 including a modular floor 102 formed with a plurality of active tiles 104. Each tile 104 may include the same or similar shape, such that multiple tiles 104 may be connected together to form the modular floor 102. For example, each tile 104 may include a polygonal shape that allows multiple tiles 104 to be connected together to form an integrated surface of the modular floor 102. The polygonal shape may be any closed plane figure bounded by three or more line segments, such as three line segments defining a triangular shape, four line segments defining a quadrilateral shape, or more than four line segments defining another polygonal shape (e.g., six line segments defining a hexagonal shape, among other suitable shapes). In such examples, any number of tiles 104 may be connected together to define the modular floor 102 of a desired size and shape. The various tiles 104 may be coupled together (e.g., via interlocking or coupling features) or the tiles 104 may be positioned adjacent one another to define the modular floor 102.

As described herein, the motion system 100 may provide or facilitate motion of one or more objects 110 on the modular floor 102. For instance, the motion system 100 may move one or more objects 110 across the modular floor 102, such as from a first location to a second location on the modular floor 102. Additionally, or alternatively, the motion system 100 may allow one or more user participants 114 to move across the modular floor 102 or walk/run on the modular floor 102, such as part of an exercise program, a gaming system, a control system, or the like. Such examples are non-limiting, and the modular floor 102 may provide or facilitate motion of any object positioned at least partially on the modular floor 102. For example, in some embodiments, the modular floor 102 may provide or facilitate motion of ride vehicles, gaming objects, containers, or any other object placed or positioned on the modular floor 102.

In one example, the modular floor 102 may be operated to allow a user participant 114 to walk or run under the user's own power. In such examples, a set of tiles 104 (or at least components of the set of tiles 104) associated with the present location and a predicted travel path 120 of the user participant 114 may be operated concurrently and in a like manner to move in another direction 122, such as opposite the current or predicted travel path 120. In this manner, the motion system 100 may control a position of the user participant 114 on the modular floor 102 (e.g., maintained at a specific location), even while the user participant 114 is walking or running, such as to limit the user participant 114 from walking off the modular floor 102 and/or to avoid a collision with another object 110 or user participant 114 on the modular floor 102. The motion 122 imparted to the user participant 114 may slow the movement of the user participant 114 relative to the modular floor 102 (e.g., the user participant 114 moves at a rate that is slower than the user's walking/running pace), halt the relative motion (e.g., the user participant 114 effectively walks/runs in place), or increase the relative motion (e.g., the user participant 114 moves at a rate that is faster than the user's walking/running pace).

In one example, the motion system 100 may be used to support independent movement of multiple (e.g., two or more) user participants 114. For instance, as shown, the motion system 100 may support a first user participant 114A moving (e.g., walking, running, etc.) along a first travel path 120A, and a second user participant 114B moving (e.g., walking, running, etc.) along a second travel path 120B that differs from the first travel path 120A. In such examples, the motion system 100 may impart respect motions 122A, 122B on the first and second user participants 114A, 114B, such as in a manner as described above. The motions 122A, 122B imparted to the user participants 114A, 114B may be independent and concurrent, even while different in the example illustrated. In some examples, the modular floor 102 may be configured to move or facilitate movement of an object 110 or user participant 114 in any direction (e.g., any lateral direction across the modular floor 102), such that the modular floor 102 may be considered an omnidirectional actuated floor.

The motion control described herein may be provided by one or more disk assemblies 130 of the motion system 100. As shown, each tile 104 may include one or more disk assemblies 130, such as a plurality of disk assemblies 130. In such examples, the disk assemblies 130 may support the one or more objects 110 or user participants 114 on the modular floor 102. The disk assemblies 130 may be operated to move the objects 110/user participants 114 on the modular floor 102, such as in a manner as described herein. For example, the disk assemblies 130 may engage the objects 110/user participants 114 so as to move the objects 110/user participants 114 as the disk assemblies 130 are operated, as described herein.

Any of the features, components, and/or parts, including the arrangements and configurations thereof shown in FIG. 1 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1.

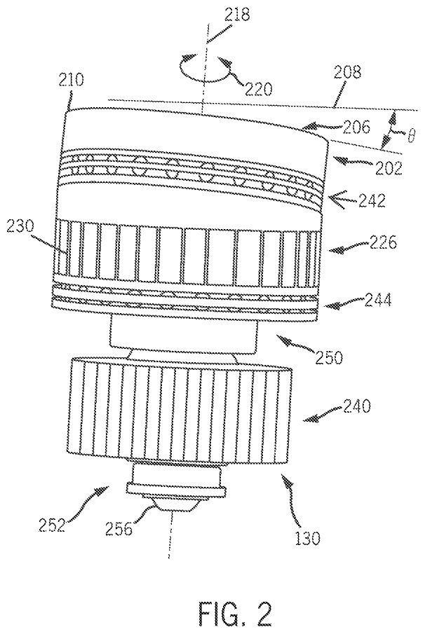

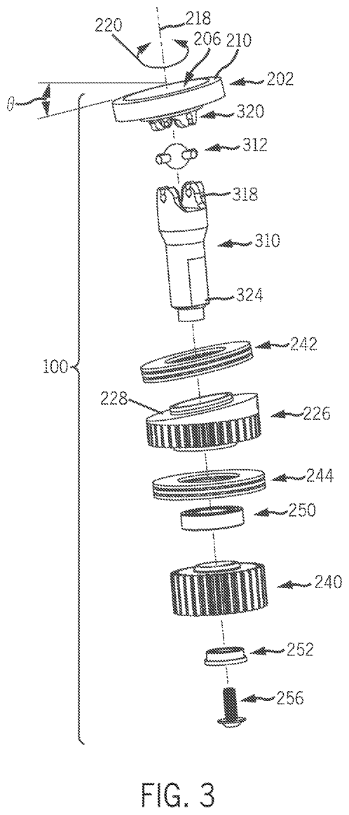

FIG. 2 illustrates an example disk assembly 130 for use in a system of the present description (e.g., motion system 100, described above), such as with a plurality of other disk assemblies 130 in an active tile 104. FIG. 3 illustrates an exploded view of the disk assembly 130. The disk assembly 130 may include a contact disk 202. The contact disk 202 may be at a first end 204 (e.g., an outer or exposed end) of the disk assembly 130 and includes an upper surface 206. In one example, the upper surface 206 may be used in the modular floor 102 described herein, such as with a plurality of other surfaces to support and move an object 110. The contact disk 202 may be positioned and/or supported in the disk assembly 130 so as to place the upper surface 206 at a tilt angle θ, such as relative to the plane 208 of the active tile 104. In one example, the upper surface 206 may include a contact surface 210 defined by a raised segment or edge relative to the rest of the upper surface 206. In such examples, the contact surface 210 (along with similar segments/portions of other contact disks in an active tile 104) may contact and support an object placed on the disk assembly 130. The tilt angle θ may be an angle of 5 to 60 degrees, with about 8 to 15 degrees being useful in some examples, and about 10 degrees (e.g., 9.5 to 10.5 degrees) being useful in one implementation.

During use, the contact disk 202 may be rotated about a rotation axis 218, such as shown by arrows 220. As shown, the rotation axis 218 extends at a non-orthogonal angle to the plane of the upper surface 206. In this manner, the contact surface 210 of the contact disk 202 may be positioned at a predefined location relative to the rotation axis 218 during operation of the disk assembly 130, such as to move a supported object in a desired direction, as described herein. For example, the disk assembly 130 may include a swashplate 226 provided with an angled or tilted surface 228 to support the contact disk 202 at the tilt angle θ. The swashplate 226 may be drivable to selectively change where the contact surface 210 is located relative to the rotation axis 218. For instance, the swashplate 226 may be drivable via outer teeth 230 as shown in FIG. 2, be belt driven, or the like. In such examples, selective positioning of the contact surface 210 via rotation of the swashplate 226 may control which direction a supported object is moved. In one example, the swashplate 226 may remain stationary or fixed in place relative to the rotation axis 218 during the rotation 220 of the contact disk 202.

The disk assembly 130 may include various drive components and bearings to support to facilitate rotation of the contact disk 202 under load. For example, the disk assembly 130 may include a gear 240 for rotating the contact disk 202 about the rotation axis 218, as detailed herein. A first thrust bearing 242 may be positioned between the contact disc and the swashplate 226, such as to reduce friction between the contact disc and the swashplate 226. A second thrust bearing 244 may be positioned between the swashplate 226 and the gear 240, such as to reduce friction between the swashplate 226 and the gear 240. The first and second thrust bearings 242, 244 may be configured to transfer a load on the contact disk 202 downward into the disk assembly 130 (e.g., into the stack of components of the disk assembly 130). For instance, the first thrust bearing 242 may transfer a downward load from the contact disk 202 onto the swashplate 226, and the second thrust bearing 244 may transfer the downward load from the swashplate 226 onto the gear 240. In some examples, the disk assembly 130 may include a top bearing 250 and a bottom bearing 252, such as for the purposes described below. A fastener 256 may secure the components of the disk assembly 130 together as an operable unit.

Referring to FIG. 3, the disk assembly 130 may include a drive shaft 310. The drive shaft 310 may be coupled to the contact disk 202 and driven by the gear 240. For instance, the disk assembly 130 may include a U-joint 312 pivotally coupled to both an end 318 of the drive shaft 310 and an underside 320 of the contact disk 202. The U-joint 312 may allow the contact disk 202 to be rotated while the high-point or contact surface 210 of the contact disk 202 is turned or redirected via the swashplate 226 to change the tilt direction or disk orientation of the contact disk 202 (e.g., to change the location of the contact surface 210 relative to the rotation axis 218). The drive shaft 310 may be coupled to the gear 240 (e.g., via a keyed engagement 324) such that rotation of the gear 240 rotates the drive shaft 310. In such examples, rotation of the gear 240 causes the drive shaft 310 to rotate, which, in turn, causes the contact disk 202 to rotate about the rotation axis 218. With continued reference to FIG. 3, the top and bottom bearings 250, 252 may rotationally support the drive shaft 310, such as centering the drive shaft 310 within the disk assembly 130.

According to various examples described herein, the contact disk 202 is supported at the tilt angle θ by the tilted surface 228 of the swashplate 226 and then selectively rotated 220 about the rotation axis 218 while the swashplate 226 remains stationary, such as to move an object supported upon the contact surface 210 of the upper surface 206. Rotation 220 may be provided through a disk rotation mechanism (which includes at least the gear 240) in the disk assembly 130 that works in combination with a drive system (not shown in FIGS. 2-3) (e.g., one or more motors driving belts, screw drives, gears, or the like to impart motion on one or more components of the disk rotation mechanism such as upon the outer teeth 230 of the gear 240).

The upper surface 206 is circular in shape in the illustrated embodiment, with the contact surface 210 being an outer ring-shaped surface or lip configured to engage surfaces of a supported object. The contact disk 202 is positioned or supported at the disk or tilt angle θ (e.g., an angle in the range of 5 to 60 degrees or the like as measured between a horizontal plane and the upper surface 206 of the contact disk 202). Such configurations cause a raised edge or portion of the contact surface 210 to contact and move an object (e.g., a person, a ride vehicle, a container, or any other object) supported upon the contact disk 202. The raised edge/segment may be a fraction of the contact surface 210, such as in the range of 1/10 to ⅖ of the available surface, depending on the magnitude of the tilt angle θ.

Each disk assembly 130 may be adapted to allow the contact disk 202 to be oriented as desired to set the location of the contact surface 210 relative to the rotation axis 218. For instance, the contact disk 202 may be rotated relative to the rotation axis 218, such as by rotation of the swashplate 226 about the rotation axis 218, to orient the contact disk 202 relative to the rotation axis 218, as described above. In such examples, the orientation of the contact surface 210 relative to the rotation axis 218 may define the direction a supported object is moved by the disk assembly 130.

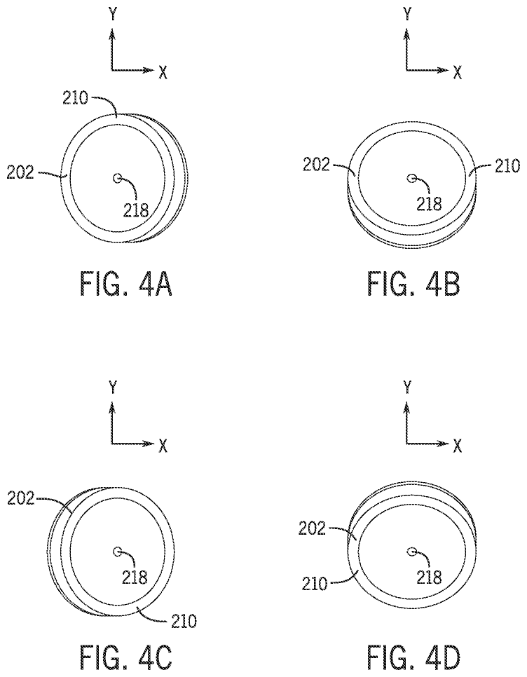

For example, FIGS. 4A-4D illustrate various orientations of the contact disk 202 that define respective directions a supported object is moved by the disk assembly 130. Referring to FIG. 4A, the tilt direction or disk orientation of the contact disk 202 may be set with the contact surface 210 at the “top” of the contact disk 202 (when looking at the page containing FIG. 4A). If the contact disk 202 is rotated clockwise about the rotation axis 218, a supported object may be moved in a positive X direction or to the right when looking at the page containing FIG. 4A. Conversely, if the contact disk 202 is rotated counterclockwise about the rotation axis 218, the supported object may be moved in a negative X direction or the left when looking at the page containing FIG. 4A.

Referring to FIG. 4B, the tilt direction or disk orientation of the contact disk 202 may be set with the contact surface 210 at the “right” of the contact disk 202 (when looking at the page containing FIG. 4B). If the contact disk 202 is rotated clockwise about the rotation axis 218, a supported object may be moved in a negative Y direction or downwards when looking at the page containing FIG. 4B. Conversely, if the contact disk 202 is rotated counterclockwise about the rotation axis 218, the supported object may be moved in a positive Y direction or upwards when looking at the page containing FIG. 4B.

Referring to FIG. 4C, the tilt direction or disk orientation of the contact disk 202 may be set with the contact surface 210 at the “bottom” of the contact disk 202 (when looking at the page containing FIG. 4C). If the contact disk 202 is rotated clockwise about the rotation axis 218, a supported object may be moved in a negative X direction or to the left when looking at the page containing FIG. 4C. Conversely, if the contact disk 202 is rotated counterclockwise about the rotation axis 218, the supported object may be moved in a positive X direction or the right when looking at the page containing FIG. 4C.

Referring to FIG. 4D, the tilt direction or disk orientation of the contact disk 202 may be set with the contact surface 210 at the “left” of the contact disk 202 (when looking at the page containing FIG. 4D). If the contact disk 202 is rotated clockwise about the rotation axis 218, a supported object may be moved in a positive Y direction or upwards when looking at the page containing FIG. 4D. Conversely, if the contact disk 202 is rotated counterclockwise about the rotation axis 218, the supported object may be moved in a negative Y direction or downwards when looking at the page containing FIG. 4D.

During any particular operation period used to move an object in a particular direction, the components of the disk assembly 130 may be configured to allow the contact disk 202 to be oriented in any of the four orientations or disk directions illustrated in FIGS. 4A-4D (or to any intermediate position between these four orientations) and to concurrently allow the contact disk 202 to be rotated at a desired rate or speed about the rotation axis 218, while remaining at the tilt angle θ at the particular disk face orientation/direction. As a result, the disk assemblies 130 may move an object 100 or user participant 114 along (or allow a user participant 114 to walk/run in) any direction across the modular floor 102. In this manner, the disk assemblies 130 may define an omnidirectional actuated floor.

Arrays or pluralities of the disk assemblies 130 may be combined into a single tile 104, and multiple tiles 104 may be combined to provide the modular floor 102 described herein, or can be used in combination to provide a large floor or platform to move supported objects 110. In such embodiments, each drive assembly may be driven independently; however, it may be useful in some embodiments to concurrently drive an array or subset of the disk assemblies 130 used to make up a support floor/platform, such as by orienting and driving/rotating each contact disk 202 in an active tile 104 similarly (e.g., drive each drive assembly in an active tile 104 concurrently and similarly to move an object on the tile 104 in a particular direction and at a particular speed).

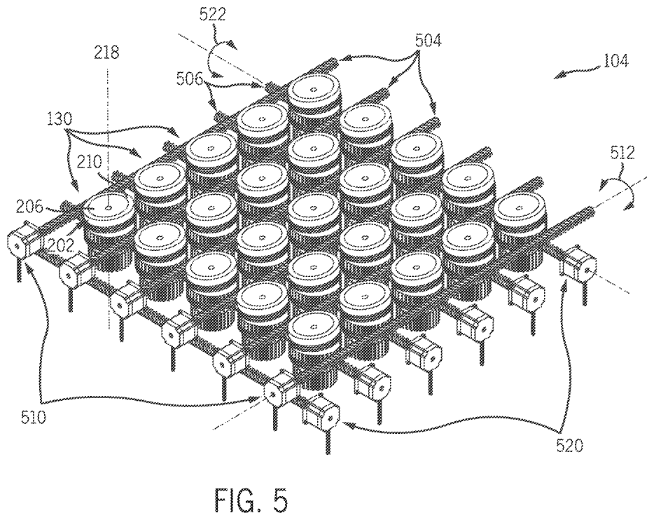

Accordingly, FIG. 5 illustrates a portion of an active tile 104 including an array or plurality of disk assemblies 130. Referring to FIG. 5, an array or plurality of disk assemblies 130 may be arranged in a pattern. For example, multiple disk assemblies 130 may be arranged in a rectangular pattern of parallel rows and columns, although other configurations are contemplated. The disk assemblies 130 may include parallel rotation axes 218 with the upper surfaces 206 facing a single direction. For example, each contact disk 202 may be oriented to have the same disk direction or to have its tilt angle oriented in the same way. The disk assemblies 130 may be driven together as a set or concurrently to rotate at the same rate and in the same direction about their rotation axes 218. In this manner, the plurality of disk assemblies 130 (or a subset of the disk assemblies 130) may move an object supported thereon in the same direction and at the same rate.

In the embodiment shown in FIG. 5, first lead screws 504 are positioned to contact the outer teeth 230 of each swashplate 226, and second lead screws 506 are positioned to contact the geared/toothed outer surface of each gear 240. One or more drive motors 510 may be selectively controlled to rotate 512 the first lead screws 504 as needed/desired to set the tilt direction or disk orientation of each contact disk 202 (e.g., to orient the contact disks 202 by rotating the swashplates 226 about their respective rotation axis 218), such as to position raised edges of the contact disks 202 concurrently in a desired location. Stated differently, rotation of the first lead screws 504 by the drive motors may cause the swashplates 226 to rotate about their respective rotation axes 218, which, in turn, causes the supported contact disks 202 to likewise rotate to position the contact surfaces 210 at a new location.

Concurrently or at a different time, one or more spin motors 520 may be selectively controlled to rotate the second lead screws 506, thereby driving the gears 240 to rotate (e.g., at the same rate). Rotation of the gears 240 may cause the contact disks 202 to rotate, with the direction of rotation of the contact disks 202 set by a direction of rotation 522 of the second lead screws 506. Similarly, the rate of rotation of the contact disks 202 may be set by the rate of rotation 522 of the second lead screws 506.

Such examples are illustrative only, and the modular floor 104 may be operated using other systems and configurations. For instance, the contact disks 202 may be rotated via intermeshing gears, among other examples. In some examples, one or more (e.g., each) contact disks 202 may be rotated via a gear train including multiple gears. In such examples, one or more motors (e.g., spin motors 510 and/or 520) may be selectively controlled to rotate the gears, thereby causing the contact disks 202 to rotate.

Any of the features, components, and/or parts, including the arrangements and configurations thereof shown in any one of FIGS. 2-5 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in any one of FIGS. 2-5.

The embodiments illustrated in FIGS. 1-5 are non-limiting examples for providing a motion system including a modular floor formed with a plurality of active tiles, the active tiles having one or more disk assemblies with a rotatable, angled disk and with mechanisms for rotating/spinning the disk and for orienting the disk to have its raised edge/portion in a desired location to direct a supported object in a desired direction during disk rotation. Thus, the motion system 100, modular floor 102, active tiles 104, and disk assemblies 130, described above, are illustrative only, and other configurations are contemplated. In one example, the systems and elements described herein (e.g., the tiles 104 and disk assemblies 130) may be similar to those described in U.S. patent application Ser. No. 15/790,124, now U.S. Pat. No. 10,416,754 B2, and U.S. patent application Ser. No. 16/135,952, now U.S. Pat. No. 10,732,197 B2, the disclosures of which are hereby incorporated by reference for all purposes.

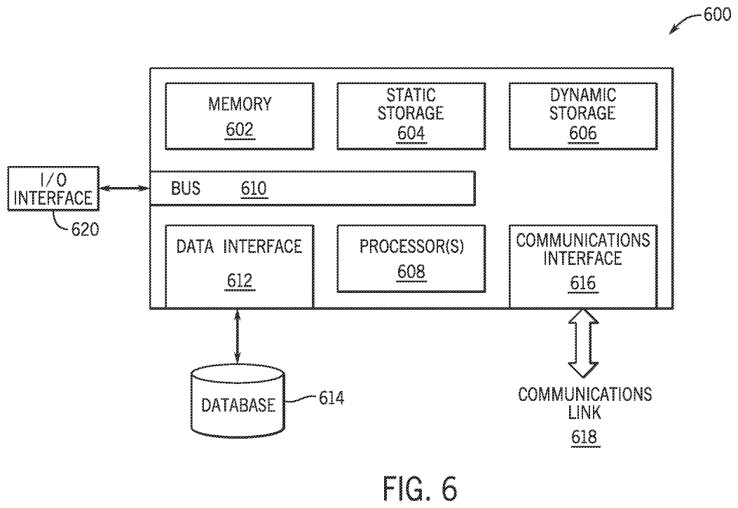

FIG. 6 illustrates an example computing system 600 for implementing various examples described herein. For example, in various embodiments, components of the motion system 100 or other systems described herein may be implemented by one or several computing systems 600. This disclosure contemplates any suitable number of computing systems 600. For example, the computing system 600 may be a server, a desktop computing system, a mainframe, a mesh of computing systems, a laptop or notebook computing system, a tablet computing system, an embedded computer system, a system-on-chip, a single-board computing system, or a combination of two or more of these. Where appropriate, the computing system 600 may include one or more computing systems; be unitary or distributed; span multiple locations; span multiple machines; span multiple data centers; or reside in a cloud, which may include one or more cloud components in one or more networks.

Computing system 600 includes a bus 610 (e.g., an address bus and a data bus) or other communication mechanism for communicating information, which interconnects subsystems and devices, such as processor 608, memory 602 (e.g., RAM), static storage 604 (e.g., ROM), dynamic storage 606 (e.g., magnetic or optical), communications interface 616 (e.g., modem, Ethernet card, a network interface controller (NIC) or network adapter for communicating with an Ethernet or other wire-based network, a wireless NIC (WNIC) or wireless adapter for communicating with a wireless network, such as a WI-FI network), input/output (I/O) interface 620 (e.g., keyboard, keypad, mouse, microphone, display). In particular embodiments, the computing system 600 may include one or more of any such components.

In particular embodiments, processor 608 includes hardware for executing instructions, such as those making up a computer program. For example, a processor 608 may execute instructions for various components of the motion system 100 or other systems described herein. The processor 608 circuitry includes circuitry for performing various processing functions, such as executing specific software to perform specific calculations or tasks. In particular embodiments, I/O interface 620 includes hardware, software, or both, providing one or more interfaces for communication between computing system 600 and one or more I/O devices. Computing system 600 may include one or more of these I/O devices, where appropriate. One or more of these I/O devices may enable communication between a person and computing system 600.

In particular embodiments, the communications interface 616 includes hardware, software, or both providing one or more interfaces for communication (such as, for example, packet-based communication) between computing system 600 and one or more other computer systems or one or more networks. One or more memory buses (which may each include an address bus and a data bus) may couple processor 608 to memory 602. Bus 610 may include one or more memory buses, as described below. In particular embodiments, one or more memory management units (MMUs) reside between processor 608 and memory 602 and facilitate accesses to memory 602 requested by processor 608. In particular embodiments, bus 610 includes hardware, software, or both coupling components of computing system 600 to each other.

According to particular embodiments, computing system 600 performs specific operations by processor 608 executing one or more sequences of one or more instructions contained in memory 602. For example, instructions for the motion system 100 or other systems described herein may be contained in memory 602 and may be executed by the processor 608. Such instructions may be read into memory 602 from another computer readable/usable medium, such as static storage 604 or dynamic storage 606. In alternative embodiments, hard-wired circuitry may be used in place of or in combination with software instructions. Thus, particular embodiments are not limited to any specific combination of hardware circuitry and/or software. In various embodiments, the term “logic” means any combination of software or hardware that is used to implement all or part of particular embodiments disclosed herein.

The term “computer readable medium” or “computer usable medium” as used herein refers to any medium that participates in providing instructions to processor 608 for execution. Such a medium may take many forms, including but not limited to, nonvolatile media and volatile media. Non-volatile media includes, for example, optical or magnetic disks, such as static storage 604 or dynamic storage 606. Volatile media includes dynamic memory, such as memory 602.

Computing system 600 may transmit and receive messages, data, and instructions, including program, e.g., application code, through communications link 618 and communications interface 616. Received program code may be executed by processor 608 as it is received, and/or stored in static storage 604 or dynamic storage 606, or other storage for later execution. A database 614 may be used to store data accessible by the computing system 600 by way of data interface 612. In various examples, communications link 618 may communicate with the motion system 100 or other systems described herein.

Any of the features, components, and/or parts, including the arrangements and configurations thereof shown in FIG. 6 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 6.

In various examples, the motion and interaction of objects on a modular and omnidirectional floor may be simulated (e.g., objects 110 and/or user participants 114 positioned on modular floor 102). Simulations may be used to determine how to integrate or use the floor in different use cases, where without such a simulation the forces and mechanisms require multiple iterations to estimate and refine. In some examples, simulations may be used to imitate operation of the floor, such as for performance tuning or optimization, safety engineering, testing, training, education, etc. In some examples, the simulations may be used to show the effects of alternative conditions or courses of action. In some examples, the simulations may be used when the floor is not accessible, dangerous, or otherwise unacceptable in its current form, or to design the floor itself.

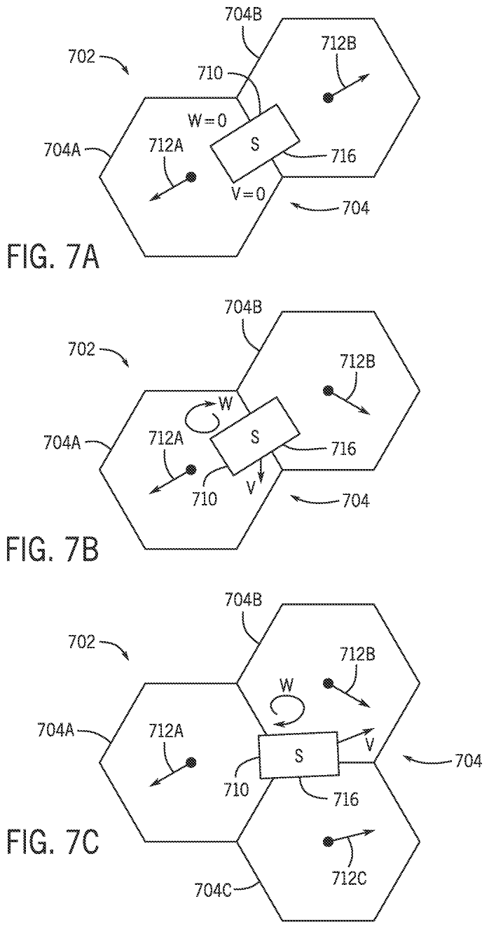

For example, FIG. 7A illustrates a modular floor 702. The modular floor 702 may be similar to the modular floor 102, described above. For instance, the modular floor 702 may include a plurality of active modules or tiles 704 configured to move independently to induce a motion of an object 710 in contact with the modular floor 702, such as in a manner as described above. The tiles 704 may be similar to the tiles 104 described above, such as including a plurality of disk assemblies 130 to control motion of an object positioned thereon. In the example shown in FIG. 7A, the modular floor 702 includes a first tile 704A and a second tile 704B, without intent to limit.

Each tile of the modular floor 702 may be configured to drive (e.g., using friction) the object 710 to a given speed. For example, FIG. 7A illustrates the first and second tiles 704A, 704B acting on the object 710 in a first manner. As shown, the first tile 704A may be driven at a first velocity 712A and the second tile 704B may be driven at a second velocity 712B, with the velocity of each tile indicated with respective arrows in FIG. 7A. The object 710 may include a contact surface 716 placed across the tiles 704 of the modular floor 702. In such examples, rigid body forces of the object 710 will compete against the friction forces generated by the tiles 704 on the contact surface 716.

In the example of FIG. 7A, the speeds are equal and opposite, and the contact surface 716 has equal contact areas across the first tile 704A and the second tile 704B. If the object 710 cannot be subdivided, the object 710 will be held in place, as the actuators (e.g., the contact surfaces 210 of the disk assemblies 130, described above) slide beneath. In such examples, the contact surface 716 will include net linear and angular velocities (υ, ω) of zero. Should the contact surface 716 have unequal contact areas across the first tile 704A and the second tile 704B, or be oriented at an angle to the speeds of the tiles 704, the object 710 may be reoriented until a balance of forces is achieved (e.g., until the object 710 is oriented as shown in FIG. 7A).

FIG. 7B illustrates the first and second tiles 704A, 704B acting on the object 710 in a second manner. In FIG. 7B, the speed vector of the second tile 704B has changed, to now no longer be equal and opposite to that of the first tile 704A. In such examples, the net linear and angular velocities (υ, ω) of the contact surface 716 may cause a net kinematic and rotational motion, as a result of the competing frictional forces applied to the contact surface 716 over the two areas of contact with the first tile 704A and the second tile 704B.

FIG. 7C illustrates the modular floor 702 acting on the object 710 in a third manner, the modular floor 702 including the first tile 704A, the second tile 704B, and a third tile 704C. In FIG. 7C, the third tile 704C may be driven at a third velocity 712C, which may be different than the first velocity 712A and/or the second velocity 712B in direction and/or magnitude. In such examples, the net linear and angular velocities (υ, ω) of the contact surface 716 may cause a net twisting and linear motion, as a result of the competing frictional forces applied to the contact surface 716 over the three areas of contact with the first tile 704A, the second tile 704B, and the third tile 704C.

Any of the features, components, and/or parts, including the arrangements and configurations thereof shown in any one of FIGS. 7A-7C can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in any one of FIGS. 7A-7C.

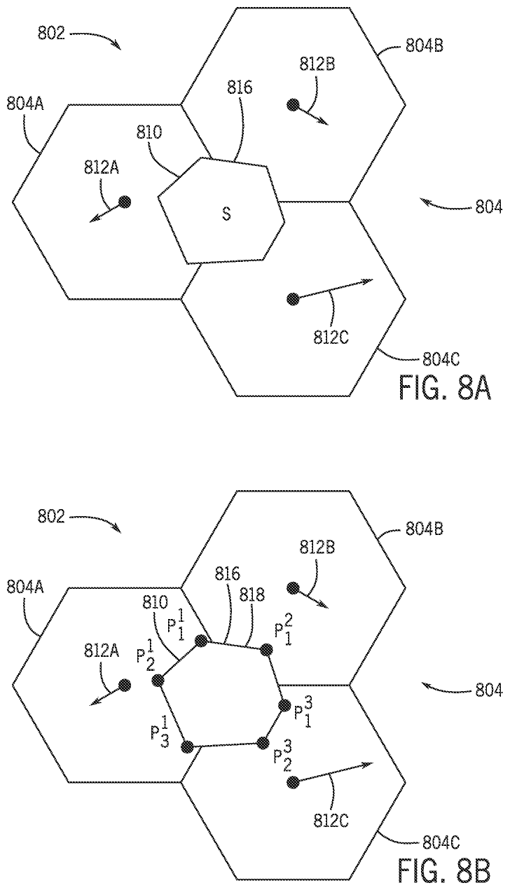

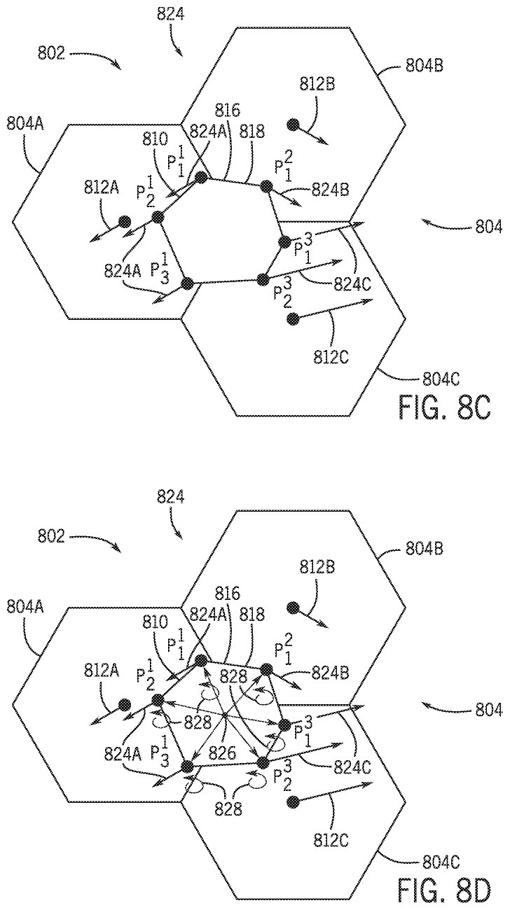

To produce realistic and computationally tractable behavior in simulation, cases such as those illustrated in FIGS. 7A-7C need to be captured accurately without the need for an explicit model of the friction-based actuation that produces the behavior in reality. To that end, FIGS. 8A-8D illustrate a method of simulating movement of an object on a multi-tile modular floor 702. The simulation solution described herein may efficiently, and in a highly scalable manner, produce realistic behavior of objects and/or user participants placed on arbitrary and omnidirectional surfaces that can be driven to produce a wide range of physical behavior. In examples, the simulations can be used to implement the modular floor into various applications. For instance, the simulations can be used to design the modular floor for a specific application, or to test the functionality and/or feasibility of the modular floor for a specific application.

FIG. 8A illustrates a modular floor 802 including a plurality of tiles 804 configured to move independently to induce a motion of an object 810 in contact with the modular floor 802, such as in a manner as described above. The tiles 804 may be similar to the tiles 104, 704 described above, such as including a plurality of disk assemblies 130 to control motion of an object positioned thereon. In the example shown in FIG. 8A, the modular floor 802 includes a first tile 804A, a second tile 804B, and a third tile 804C driven at first velocity 812A, a second velocity 812B, and a third velocity 812C, respectively, although other configurations are contemplated. As shown, the object 810 may include a contact surface 816 making contact with the modular floor 802. The contact surface 816 may include a variety of shapes, such as based on the object's shape and configuration. For example, the contact surface 816 may include a polygonal shape having multiple line segments and vertices.

FIGS. 8B-8D illustrate one example of simulating movement of the contact surface 816 on the modular floor 802. Referring to FIG. 8B, a set of particles Pₙ^{m} may be generated along a boundary 818 of the contact surface 816. In one example, the particles P may be generated at the vertices of the contact surface 816. Additionally, or alternatively, the particles P may be generated along the line segments, such as midway between vertices, equidistantly spaced between vertices, equidistantly spaced along the boundary 818, or the like. Depending on the shape of the contact surface 816 and the position of the contact surface 816 on the tiles 804, each tile may include zero, one, or multiple particles P.

The generated particles P are distinguished in FIGS. 8B-8D by tile/module and number. For example, the particles P positioned on the first tile 804A may be distinguished by a first superscript, with the particle number distinguished by subscript (e.g., P₁¹, P₂¹, P₃¹, etc.). Similarly, the particles P positioned on the second tile 804B may be distinguished by a second superscript, with the particle number distinguished by subscript (e.g., P₁², etc.). The particles P positioned on the third tile 804C may be distinguished by a third superscript, with the particle number distinguished by subscript (e.g., P₁³, P₂³, etc.).

Referring to FIG. 8C, each particle P may be assigned a linear velocity 824. The linear velocity 824 may be based on a velocity/speed of the tile on which the particle P is positioned. For example, the particles P₁¹, P₂¹, P₃¹ contained within or positioned on/over the first tile 804A may be assigned the first velocity 812A of the first tile 804A (e.g., a first linear velocity 824A). Similarly, the particles P₁² contained within or positioned on/over the second tile 804B may be assigned the second velocity 812B of the second tile 804B (e.g., a second linear velocity 824B), and the particles P₁³, P₂³ contained within or positioned on/over the third tile 804C may be assigned the third velocity 812C of the third tile 804C (e.g., a third linear velocity 824C). The first linear velocity 824A may be different than the second linear velocity 824B and/or the third linear velocity 824C.

Referring to FIG. 8D, a center of rotation 826 of the contact surface 816 may be determined. The center of rotation 826 may be the point about which the contact surface 816 rotates. The center of rotation 826 may be the center of mass of the contact surface 816. The center of rotation 826 may be computed by averaging the particle positions, although other configurations are contemplated. Each particle P may be assigned an angular velocity 828. The angular velocity 828 may be based on a vector product of the particle's linear velocity 824 and distance from the center of rotation 826. The angular velocity 828 may be unique to each particle P based on the particle's unique linear velocity 824 and distance combination.

With continued reference to FIG. 8D, the motion of the object 810/contact surface 816 may be simulated or otherwise determined based on the assigned linear and angular velocities 824, 828. For example, the assigned linear and angular velocities 824, 828 may be averaged. In this manner, the motion of the object 810 on the modular floor 802 may be determined or otherwise simulated.

In one example, torsional and/or tension stresses may be calculated (e.g., by a processor). For instance, a standard deviation of the assigned linear velocities 824 may be calculated. In such examples, the standard deviation of linear velocities 824 may provide a measure of the tension stress applied to at least one of the object 810 or the modular floor 802 (e.g., both the object 810 and the modular floor 802). In one example, a standard deviation of the assigned angular velocities 828 may be calculated. The standard deviation of angular velocities 828 may provide a measure of the torsional stress applied to at least one of the object 810 or the modular floor 802 (e.g., both the object 810 and the modular floor 802). In this manner, the stresses felt by the tiles 804 and the object 810 may be determined, allowing the simulation, with thresholding, to predict any damage that will be applied to the tile's motors or the object 810.

Any of the features, components, and/or parts, including the arrangements and configurations thereof shown in any one of FIGS. 8A-8D can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in any one of FIGS. 8A-8D.

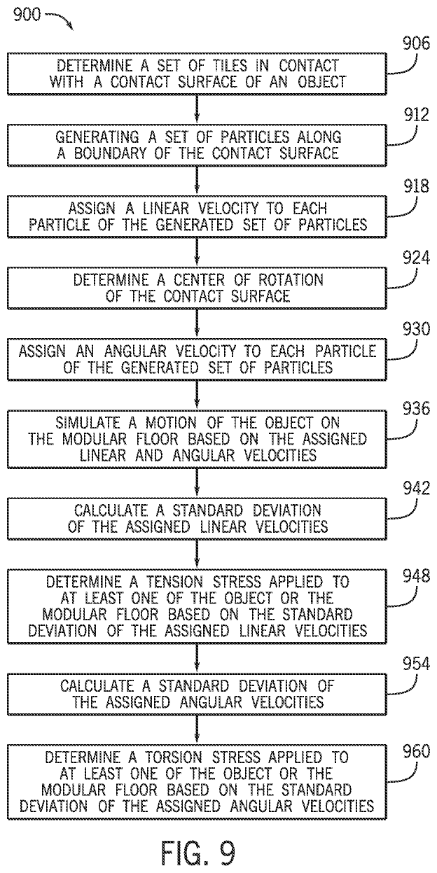

FIG. 9 illustrates a method 900 of simulating movement of an object on a multi-tile modular floor. For explanatory purposes, the method 900 is described herein with reference to FIGS. 1-8D, although the method 900 is not limited to the examples illustrated therein. For example, the method 900 may be performed by the motion system 100 and/or computing system 600 (e.g., the processor 608), described above. In one example, the method 900 may be performed by a computer or computer system, such as on one or more processing elements. Note that one or more operations in FIG. 9 may be combined, omitted, and/or performed in a different order, as desired.

As described herein, the method 900 may be associated with simulating or otherwise determining a motion of an object in contact with a modular floor, the modular floor including a plurality of tiles configured to move independently to induce a motion of the object on the modular floor. In examples, the object may include a contact surface contacting one or more tiles of the modular floor. Although the method is described with reference to a modular floor (e.g., modular floor 802), the simulation methods described herein may be used to predict the behavior of any system of actuators of multiple surfaces in contact, such as conveyor belts or platforms. Thus, the simulation methods described herein are not limited to the applications illustrated.

At block 906, the method 900 includes determining a set of tiles in contact with the object. Block 906 may include determining the set of tiles in contact with the contact surface of the object. In one example, the number and/or identity of the tiles contacting the contact surface of the object may be determined based on arbitrary mesh collision.

At block 912, the method 900 includes generating a set of particles along a boundary of the contact surface. For example, particles may be generated at and/or between the vertices of the contact surface, such as in a manner as described above.

At block 918, the method 900 includes assigning a linear velocity to each particle of the generated set of particles. The assigned linear velocity may be based on a velocity of the tile on which the particle is positioned. For example, particles contained within or positioned on/over a first tile of the modular floor may be assigned the velocity of the first tile. Similarly, particles contained within or positioned on/over a second tile, a third tile, or an n^{th} tile of the modular floor may be assigned the velocity of the second tile, the third tile, the n^{th} tile, respectively, such as in a manner as described above.

At block 924, the method 900 includes determining a center of rotation of the contact surface, such as in a manner as described above. In some examples, block 918 may include determining the center of rotation based on an average of the particle positions.

At block 930, the method 900 includes assigning an angular velocity to each particle of the generated set of particles, such as in a manner as described above. For example, the assigned angular velocity may be based on a vector product of the particle's linear velocity and distance from the center of rotation.

At block 936, the method 900 includes simulating the motion of the object on the modular floor based on the assigned linear and angular velocities. In examples, block 936 may include averaging the assigned linear and angular velocities to simulate the motion of the object. In such examples, block 936 may include simulating the motion of the object on the modular floor based on the averages of the assigned linear and angular velocities.

At block 942, the method 900 includes calculating a standard deviation of the assigned linear velocities. At block 948, the method 900 includes determining a tension stress applied to at least one of the object or the modular floor. The tension stress may be determined based on the standard deviation of the assigned linear velocities.

At block 954, the method 900 includes calculating a standard deviation of the assigned angular velocities. At block 960, the method 900 includes determining a torsion stress applied to at least one of the object or the modular floor. The torsion stress may be determined based on the standard deviation of the assigned angular velocities.

In examples, the simulations may be used to design, test, or otherwise model a modular floor (e.g., modular floor 102, modular floor 702, and/or modular floor 802). For instance, the simulations may be used to predict one or more forces to enable the design and installation of the modular floor in different scenarios (e.g., that may not be possible without simulation due to difficulty of accurately calculating the actual forces, etc.). In some examples, the simulations may be utilized to create an installation design, or to prove the feasibility or functionality of the installation design. In some examples, the simulations may be used to predict movements of one or more objects on the modular floor in different scenarios (e.g., that may not be possible or feasible without simulation due to difficulty of accurately predicting actual movement, etc.). In examples, the simulations may be output on a display to visualize to a user.

The description of certain embodiments included herein is merely exemplary in nature and is in no way intended to limit the scope of the disclosure or its applications or uses. In the included detailed description of embodiments of the present systems and methods, reference is made to the accompanying drawings which form a part hereof, and which are shown by way of illustration specific to embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The included detailed description is therefore not to be taken in a limiting sense, and the scope of the disclosure is defined only by the appended claims.

From the foregoing it will be appreciated that, although specific embodiments of the invention have been described herein for purposes of illustration, various modifications may be made without deviating from the spirit and scope of the invention.

The particulars shown herein are by way of example and for purposes of illustrative discussion of the preferred embodiments of the present invention only and are presented in the cause of providing what is believed to be the most useful and readily understood description of the principles and conceptual aspects of various embodiments of the invention. In this regard, no attempt is made to show structural details of the invention in more detail than is necessary for the fundamental understanding of the invention, the description taken with the drawings and/or examples making apparent to those skilled in the art how the several forms of the invention may be embodied in practice.

As used herein and unless otherwise indicated, the terms “a” and “an” are taken to mean “one”, “at least one” or “one or more”. Unless otherwise required by context, singular terms used herein shall include pluralities and plural terms shall include the singular.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “above,” and “below” and words of similar import, when used in this application, shall refer to this application as a whole and not to any particular portions of the application.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. A system for simulating a motion of an object on a modular floor comprising a plurality of tiles configured to move independently, the system comprising:
a processor configured to:
generate a set of particles along a boundary of a contact surface of the object;
assign a linear velocity to each particle of the set of particles;
assign an angular velocity to each particle of the set of particles; and
simulate the motion of the object on the modular floor based on the assigned linear and angular velocities.

2. The system of claim 1, wherein the processor is configured to output on a display to visualize the simulation to a user.

3. The system of claim 1, further comprising the modular floor, wherein the processor is configured to determine a set of tiles of the modular floor in contact with the object based on arbitrary mesh collision.

4. The system of claim 1, wherein the linear velocity assigned to each particle is based on a velocity of the tile on which the particle is positioned.

5. The system of claim 1, wherein the processor is configured to determine a center of rotation of the contact surface based on an average of the particle positions, and wherein the angular velocity assigned to each particle is based on a vector product of the particle's linear velocity and distance from the center of rotation.

6. The system of claim 1, wherein the assigned linear and angular velocities are averaged to simulate the motion of the object.

7. The system of claim 1, wherein the processor is configured to calculate a standard deviation of the assigned linear velocities.

8. The system of claim 7, wherein the processor is configured to determine a tension stress applied to at least one of the object or the modular floor based on the standard deviation of the assigned linear velocities.

9. The system of claim 1, wherein the processor is configured to calculate a standard deviation of the assigned angular velocities.

10. The system of claim 9, wherein the processor is configured to determine a torsion stress applied to at least one of the object or the modular floor based on the standard deviation of the assigned angular velocities.

11. A method comprising:
generating, by a processor, a set of particles along a boundary of a contact surface of an object in contact with a modular floor, the modular floor comprising a plurality of tiles configured to move independently to induce a motion of the object on the modular floor;
assigning, by the processor, a linear velocity to each particle of the set of particles;
assigning, by the processor, an angular velocity to each particle of the set of particles; and
simulating, by the processor, the motion of the object on the modular floor based on the assigned linear and angular velocities.

12. The method of claim 11, further comprising determining, by the processor, a set of tiles in contact with the object based on arbitrary mesh collision.

13. The method of claim 11, wherein the linear velocity assigned to each particle is based on a velocity of the tile on which the particle is positioned.

14. The method of claim 11, further comprising determining, by the processor, a center of rotation of the contact surface based on an average of the particle positions.

15. The method of claim 14, wherein the angular velocity assigned to each particle is based on a vector product of the particle's linear velocity and distance from the center of rotation.

16. The method of claim 11, wherein the simulating the motion of the object comprises averaging the assigned linear and angular velocities.

17. The method of claim 11, further comprising calculating, by the processor, a standard deviation of the assigned linear velocities.

18. The method of claim 17, further comprising determining, by the processor, a tension stress applied to at least one of the object or the modular floor based on the standard deviation of the assigned linear velocities.

19. The method of claim 11, further comprising calculating, by the processor, a standard deviation of the assigned angular velocities.

20. The method of claim 19, further comprising determining, by the processor, a torsion stress applied to at least one of the object or the modular floor based on the standard deviation of the assigned angular velocities.
